(19) United States
(12) Patent Application Publication
(10) Pub. No.: US 2009/0108369 A1
(43) Pub. Date: Apr. 30, 2009

(54) Radio Frequency Device of Semiconductor Type

(76) Inventor: Kyong Tae CHU, Bucheon-si (KR)

Correspondence Address: THE LAW OFFICES OF ANDREW D. FORTNEY, PH.D., P.C., 401 W FALLBROOK AVE STE 204, FRESNO, CA, 93711-5835, US

(21) Appl. No.: 12/255,594

(22) Filed: Oct. 21, 2008

(30) Foreign Application Priority Data
Oct. 24, 2007 (KR) 10-2007-0107025

(51) Int. Cl. H01L 47/00; H01L 21/44

(52) U.S. Cl. 257/369; 438/667; 257/E47.001; 257/E21.476

(57) ABSTRACT

An RF device includes a semiconductor substrate; an insulating layer thereon; a first plate type ground layer having a slot, on a top of the insulating layer; a signal line in the insulating layer beneath the first ground layer; a plurality of second ground layers in the insulating layer around the signal line; and a via hole connecting the first ground layer and the second ground layer.

The present application claims the benefit of priority under 35 U.S.C. §119 to Korean Patent Application No. 10-2007-0107025, filed on Oct. 24, 2007, the entire contents of which are incorporated herein by reference.

### FIELD OF THE INVENTION

Embodiments of the invention concern a radio frequency (RF) device of a semiconductor type.

### BACKGROUND

A complementary metal-oxide semiconductor (CMOS) device has good frequency characteristics with the development of fine processing technology. CMOS processing technology can manufacture a low-price chip as well as a system on chip (SOC), and can integrate an intermediate frequency circuit and a digital circuit, such that it has been spotlighted as the most suitable technology to manufacture a single chip for providing such functions together.

Components of an RF-CMOS or bipolar/BiCMOS device include an RF MOSFET, an inductor, a varactor, an MIM capacitor, and a resistor. For example, the inductor, which is generally considered to be a single structure on the device, occupies most of an area of a chip and has many limitations in view of high frequency characteristics because of parasitic capacitance and resistance components, according to its inner structure and material(s).

In the case of implementing the RF device using interconnects and a coplanar waveguide (CPW), since the silicon substrate generally has a low resistance value, there can be problems in that a coupling phenomenon occurs and a signal loss becomes large.

Also, in the case of implementing the RF device with a microstrip line, since the influence of substrate loss is small, but the interval between the signal line and the ground surface is small, it is difficult to obtain a high impedance value.

In order to solve the coupling problem(s) associated with the substrate, there is a method using a thick BCB substrate of 20 μm or more, so that the interval between the silicon substrate and the CPW is large. Alternatively, one may use a silicon substrate having high resistance. However, the methods have problems, such as a change in process conditions, an increased production cost, and decreased efficiency in the semiconductor manufacturing process.

### SUMMARY

An object of embodiments of the invention is to provide a semiconductor type RF device capable of efficiently interrupting or shielding a signal on a signal line and minimizing the insertion loss of the signal line by improving the structure of the signal line and a ground layer.

Also, another object of embodiments of the invention is to provide a semiconductor type RF device capable of minimizing a size of the signal line and controlling characteristics and/or the size of the signal line without changing process condition(s) by improving the structure of the signal line and the ground layer.

There is provided a semiconductor RF device according to embodiments of the invention that includes a substrate; an insulating layer on the substrate; a first plate type ground layer having a slot, on the insulating layer; a signal line in the insulating layer beneath the first ground layer; a plurality of second ground layers in the insulating layer around the signal line; and a via connecting the first ground layer and the second ground layer.

### BRIEF DESCRIPTION OF THE DRAWINGS

FIG. 1 is a cross-sectional view showing a form of an exemplary semiconductor type RF device according to a first embodiment.

FIG. 2 is a top view showing the form of the exemplary RF device according to the first embodiment.

FIG. 3 is a cross-sectional view showing a form of an exemplary semiconductor type RF device according to a second embodiment.

FIG. 4 is a top view showing the form of the exemplary RF device according to the second embodiment.

FIG. 5 is an enlarged top view showing a portion of a first ground layer of the exemplary RF device according to the second embodiment.

### DETAILED DESCRIPTION OF THE EMBODIMENTS

An exemplary semiconductor type RF device according to embodiments of the invention will be described with reference to the accompanying drawings. The exemplary semiconductor type RF device may comprise a signal line form, can be applied in various forms, such as a transmission line, an inductor, a filter, a phase shifter, etc.

In the description of various embodiments, it will be understood that when a layer (or film) is referred to as being ‘on’ another layer or substrate, it can be directly on another layer or substrate, or one or more intervening layers may also be present. Further, it will be understood that when a layer is referred to as being ‘under’ another layer, it can be directly under another layer, or one or more intervening layers may also be present. In addition, it will also be understood that when a layer is referred to as being ‘between’ two layers, it can be the only layer between the two layers, or one or more additional intervening layers may also be present.

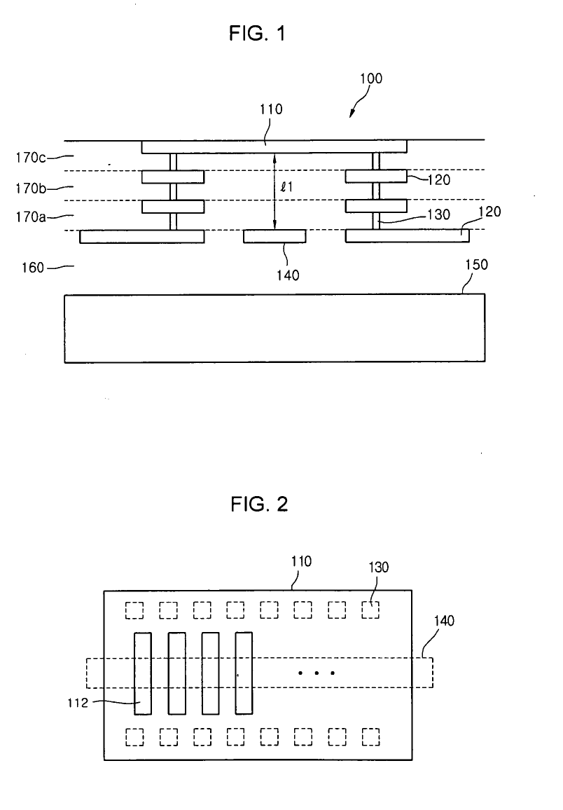

FIG. 1 is a cross-sectional view showing a form of an exemplary RF device 100 of a semiconductor type according to a first embodiment.

Referring to FIG. 1, the RF device 100 of the semiconductor type includes a second ground layer 120, a signal line 140, a first ground layer 110, and a via 130, on a substrate 150. The second ground layer 120 may comprise one or more individual metallization layers (e.g., 3 are shown in FIG. 1). The vias 130 are each generally in a via hole in the insulating layer between adjacent metallization layers.

The signal line 140 through which high frequency signals flow benefits from a surrounding ground layer so as to shield an electromagnetic signal generated from the line and stably maintain a state of the signal (e.g., its size or amplitude, phase, etc., at a given frequency).

The ground layer 110, 120 can suppress interference between adjacent signal lines, the signal line 140 and an external electromagnetic field, or an adjacent semiconductor device region and another signal line, etc., by shielding an electromagnetic signal. The electromagnetic signal can be internal or external to the signal line 140.

The semiconductor type RF device 100 according to the first embodiment generally includes two kinds of ground layers, such as a first ground layer 110 formed on or in a top metallization and/or insulation layer of the semiconductor device 100, and a second ground layer 120 in or on an inner or lower metallization and/or insulation layer of the semiconductor device 100.

An insulating layer (e.g., a premetal dielectric layer 160) is formed on the substrate 150 and a plurality of second ground layers 120 and a signal line 140 are formed on the insulating layer. The premetal dielectric layer 160 may comprise a lowermost, conformal etch stop layer (e.g., silicon nitride), a conformal buffer and/or gap-fill layer (e.g., silicon-rich oxide [SRO], TEOS [e.g., a silicon oxide formed by CVD from tetraethyl orthosilicate and oxygen], an undoped silicate glass [USG] or a combination thereof), a bulk dielectric layer (e.g., one or more silicon oxide layers doped with boron and/or phosphorous [BSG, PSG and/or BPSG]), and a capping layer (e.g., of TEOS, USG, a plasma silane [for example, silicon dioxide formed by plasma-assisted CVD of silicon dioxide from silane and oxygen], or a combination thereof, such as a bilayer of plasma silane on USG or TEOS, or a bilayer of USG on TEOS). The second ground layer 120 may be formed in (as shown) or on the premetal dielectric layer 160. When the second ground layer 120 is formed in the premetal dielectric layer 160, it may comprise a single or dual damascene copper line, which may further include an adhesive and/or barrier layer between it and the dielectric (e.g., a Ta/TaN bilayer). The signal line 140 may be formed at the same time and may comprise the same materials as the second ground layer 120, but it generally comprises a single damascene structure (i.e., no vias to the substrate 150). Alternatively, the second ground layer 120 and signal line 140 may be formed on the premetal dielectric layer 160, in which case it may comprise aluminum or an aluminum alloy (e.g., Al with up to 4 wt. % Cu, up to 2 wt. % Ti, and/or up to 1 wt. % Si), on conventional adhesion and/or barrier layers (e.g., Ti and/or TiN, such as a TiN-on-Ti bilayer), and/or covered by conventional adhesion, barrier, hillock suppression, and/or antireflective layers (e.g., Ti, TiN, WN, TiW alloy, or a combination thereof, such as a TiN-on-Ti bilayer or a TiW-on-Ti bilayer). Subsequent second ground layers 120 may be formed in or on successive insulating layers 170a-170b, which can be stacked into a plurality of layers, in the same manner as the initial second ground layer 120. In the successive insulating layers 170a-170b, the bulk dielectric layer may comprise (in addition to those described for the premetal dielectric layer 160) a low-k dielectric, such as a fluorosilicate glass (FSG), silicon oxycarbide (SiOC) or hydrogenated silicon oxycarbide (SIOCH), any of which may comprise upper and lower low-k dielectric layers above and below an intermediate etch stop layer (e.g., silicon nitride). The first ground layer 110 may be formed on or in an uppermost insulating layer 170c, in the same manner as second ground layers 120 and signal line 140.

Also, the first ground layer 110, the second ground layer 120, and the signal line 140 may comprise a metal material and can be formed by repetitively performing a insulator deposition process, a photolithography and patterning process (e.g., using a resist), an etch process, a metal deposition process, a planarization process, etc.

The signal line 140 is formed in a region beneath the first ground layer 110, that is, in an insulating layer region vertically corresponding to the first ground layer 110 and the second ground layer 120, formed around the signal line 140.

Also, the first ground layer 110 may largely be formed to overlap the second ground layer 120 (e.g., include the region in which the second ground layer 120 is formed in a vertical projection).

The first ground layer 110 and the second ground layer 120 are electrically connected through a plurality of vias in corresponding via holes, making it possible to uniformly absorb or shield an electromagnetic signal radiated from the signal line 140 (or shield the signal line 140 from an external electromagnetic field) and allow the absorbed signal(s) to have the same potential.

The first ground layer 110 having a large area exists on or over the signal line 140, such that an electric field can be biased (e.g., a biased electric field can be formed) above the signal line 140, and the effect of the electric field on the substrate 150 becomes small. Therefore, the coupling phenomenon with the substrate is reduced or eliminated, making it possible to minimize the insertion loss of the substrate and the signal line.

Also, since parasitic capacitance between the substrate 150 and the signal line 140 can be minimized, the characteristic impedance of the signal line 140 can be increased.

FIG. 2 is a top view showing the exemplary RF device according to the first embodiment and illustrating some forms of the first ground layer 110. The first ground layer 110 includes one or more slots 112 to leak an electromagnetic field from the signal line 140 toward the upper side (e.g., towards the first ground layer 110). In other words, the first ground layer 110 has a defected ground structure (DGS), making it possible to minimize an effect of electric field.

According to FIG. 2, a plurality of slots 112 may be arranged in a central portion of the first ground layer 100, and the vias 130 may be connected to sides of the first ground layer 100 at opposite ends of the slots 112. To improve lateral shielding, two or more of the vias 130 can be joined in an extended trench along the length of the signal line 140, although joining vias 130 in such a manner may slightly weaken the resulting structure.

The signal line 140 is below a region in which the slots 112 are formed. As a result, most of the electromagnetic signals radiated from the signal line 140 may be leaked to the outside through the slots 112.

Also, the first ground layer 110 having the DGS shows a slow wave phenomenon, such that a length of the transmission line can be shortened according to a frequency and/or wavelength (e.g., the signal line 140 may have a length that corresponds to the frequency and/or wavelength of the signal to be carried thereon in a predetermined manner).

Therefore, the first ground layer 110 is positioned on or over the top layer, making it possible to minimize the length of the signal line 140.

As the DGS of the first ground layer 110 approaches the metal structure, the semiconductor device, etc., the effect thereof is degraded. In the exemplary first embodiment, the first ground layer 110 is formed in or on the top insulating layer 170c and has a structure electrically connected with the second ground layer 120, such that the semiconductor substrate 150 having semiconductor devices thereon can be sufficiently spaced from the signal line 140.

Also, based on the signal line 140, the first ground layer 110 is formed in the opposite direction to the substrate 150, making it possible to stably maintain the effects of the DGS.

Meanwhile, as the slots 112 are formed in the first ground layer 110, the characteristic impedance of the signal line 140 may increase. The numerical values of the capacitance can be changed by controlling a distance Λ1 between the first ground layer 110 (containing the slots 112) and the signal line 140 (see FIG. 1). Therefore, the characteristic impedance of the signal line 140 can be controlled according to a frequency of the signal on the signal line 140.

In order to control the length between the first ground layer 110 and the signal line 140, a thickness of the insulating layer can be increased by increasing the number of second ground layers 120 or changing the position of the signal line 140 on the insulating layer 150.

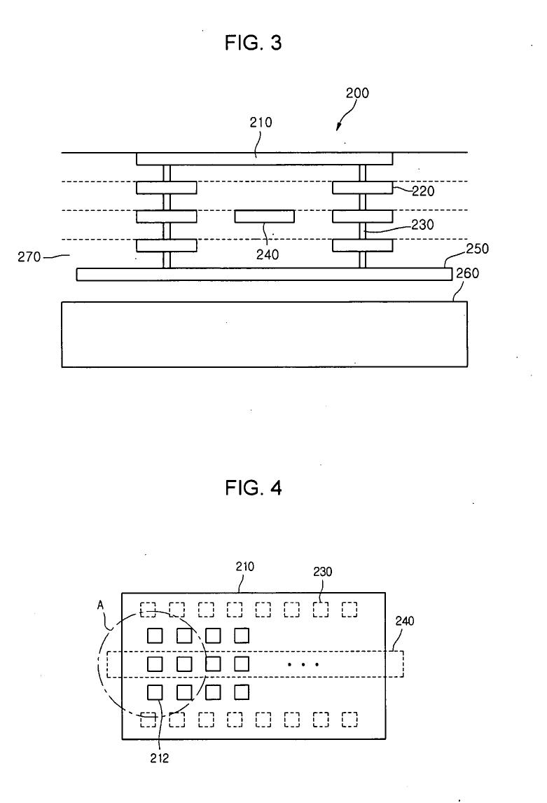

FIG. 3 is a cross-sectional view showing a form of an exemplary RF device of a semiconductor type according to a second embodiment.

Referring to FIG. 3, an exemplary semiconductor type RF device 200 according to the second embodiment includes a third ground plane or layer 250, a (plurality of) second ground plane(s) or layer(s) 220, a first ground plane or layer 210, a signal line 240, and a plurality of vias 230 are formed on a substrate 260.

The exemplary RF device 200 according to the second embodiment is different from the RF device 100 of the first embodiment in that the third ground plane or layer 250, which performs a main ground plate like the first insulating layer 210, is further provided under the signal line 240 (e.g., on a bottom or premetal dielectric layer 270).

The third ground plane or layer 250 may be formed in a wide plate form similar to that of the first ground plane or layer 210. The third ground plane or layer 250 may overlap the second ground layer(s) 220 (e.g., be formed to include the region in which the second ground layer(s) 220 and the signal line 240 are formed in a vertical projection).

The first ground plane or layer 210, second ground plane(s) or layer(s) 220, and third ground plane or layer 250, which are electrically connected through the vias 230, can shield the electromagnetic signal radiated from the signal line 240 (and, conversely, the signal line 240 from external electromagnetic fields) in every aspect. Other structural properties and effects of the RF device 200 of the semiconductor type according to the second embodiment may be similar to those according to the first embodiment; the overlapping description will be omitted.

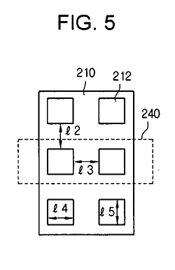

FIG. 4 is a top view showing an exemplary form of the RF device according to the second embodiment. FIG. 5 is an enlarged top view showing a portion A of a first ground layer 210 of the exemplary RF device 200 according to the second embodiment.

The first ground plane or layer 210 according to the second embodiment may have one or more slots 212, similar to the first embodiment, to have a defect ground structure. However, the first ground layer 210 according to the second embodiment is different from that according to the first embodiment in that it has a different slot structure. Also, the third ground layer 250 may have the defect ground structure in addition to the first ground layer 210.

The slot 212 according to the second embodiment may have diverse forms or shapes, such as polygonal, circular, oval, etc., instead of the line form in the first embodiment or the square form in the second embodiment shown in FIG. 4. The slot 212 in plural are arranged in the first ground layer 210, or in a central portion of the third ground layer 250, and a plurality of vias 230 connect adjacent ground layers to each other on both (e.g., opposite) sides of the slots 212.

Besides, the second embodiment is similar to the first embodiment in that the signal line 240 is below a region in which the slots are formed in the first ground layer 210, so that the electromagnetic signals from signal line 240 may leak to the outside through the slots 212, the length of the signal line 240 can be minimized, the effect of the defect ground structure can be stably maintained as the first ground layer 210 and third ground layer 250 are formed above and below the signal line 240 (e.g., on or in a top insulating layer and a bottom insulating layer). Therefore, overlapping description will be omitted.

According to the defect ground structure according to the second embodiment, the characteristic impedance of the signal line 240 can be controlled using the following method.

First, distances between (i) the first ground layer 210 and the signal line 240, and (ii) the third ground layer 250 and the signal line 240, are controlled, making it possible to change the numerical values of the capacitance.

Second, as shown in FIG. 5, the shape and size the slot 212 and distance between the slots 212 may be changed or varied. For example, if the length or width Λ4, Λ5, of the slot 212 is enlarged, and the distance Λ2, Λ3 between the slots 212 is decreased, the inductance component increases and capacitance component decreases, making it possible to enlarge the characteristic impedance.

As described above, many more embodiments may be manufactured by combining characteristics of each structure of the RF device according to the first and second embodiments. This may be exemplified as follows.

First, the first ground layer 110 according to the first embodiment may have a structure of the slot 112 according to the first embodiment. Second, the first ground layer 110 according to the first embodiment may have a structure of the slot 212 according to the second embodiment. Third, the first ground layer 210 according to the second embodiment may have a structure of slots 112, 212 according to the first embodiment and/or the second embodiment, but the third ground layer 250 does not have a slot. Fourth, the first ground layer 210 and third ground layer 210 according to the second embodiment may have the same slot structure (e.g., of the slots 112 and/or 212). Fifth, the first ground layer 210 and the third ground layer 210 according to the second embodiment may have different slot structures (e.g., the first ground layer 210 includes the slots 112, and the third ground layer 210 includes the slots 212).

The invention may achieve the following effects.

First, the electromagnetic signal radiated from (or to) the signal line can be effectively shielded, and interference with adjacent devices and/or signal lines can be prevented.

Second, coupling with the substrate may be reduced, minimized or eliminated, making it possible to minimize insertion and loss of the signal line and increase the characteristic impedance of the signal line.

Third, the size of the signal line can be minimized through the defect ground structure of the overlying and/or underlying ground planes or layers, and the effect of the defect ground structure can stably be maintained by the structure of the ground layer.

Fourth, the interval between the signal line and the ground layer(s), and the shape, size, and arrangement of the slot(s) may be varied, making it possible to control the characteristic impedance of the signal line.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is within the purview of one skilled in the art to effect such feature, structure, or characteristic in connection with other embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An RF device comprising:
a semiconductor substrate;
an insulating layer on the semiconductor substrate;
a first plate type ground layer having a slot, above the insulating layer;
a signal line on, in or above the insulating layer beneath the first ground layer;
a plurality of second ground layers in, on or above the insulating layer around the signal line; and
a via connecting the first ground layer and the second ground layer.

2. The RF device according to claim 1, wherein at least part of the first ground layer overlaps the second ground layer.

3. The RF device according to claim 1, wherein the slot is in a central part of the first ground layer, the via is outside the central part, and the signal line is below the central part.

4. The RF device according to claim 1, wherein the second ground layer is adjacent to the signal line.

5. The RF device according to claim 4, wherein the signal line is at a height greater than a lowermost second ground layer.

6. The RF device according to claim 1, further comprising a third plate type ground layer, on the insulating layer and connected to the second ground layer.

7. The RF device according to claim 6, wherein the third ground layer overlaps at least a portion of the second ground layer in a vertical projection.

8. The RF device according to claim 6, wherein the third ground layer has an equal or larger area than the first ground layer.

9. The RF device according to claim 6, wherein the third ground layer has a slot.

10. The RF device according to claim 9, wherein the slot of the first ground layer and/or the slot of the third ground layer has a line form, a polygonal form, a circular form, or an oval form.

11. The RF device according to claim 10, wherein the slot of the first ground layer or the slot of the third ground layer has the polygonal, circular, or oval form, and the form and size of the slot and an interval between adjacent slots are constant and regularly arranged.

12. The RF device according to claim 1, comprising a plurality of vias connecting the first ground layer and the second ground layer.

13. The RF device according to claim 1, comprising a plurality of slots in the first ground layer.

14. A method of making an RF device comprising:
forming an insulating layer on a semiconductor substrate;
forming a signal line and a plurality of second ground layers on, in or above the insulating layer;
depositing a first dielectric layer on or above the insulating layer, the signal line, and the plurality of second ground layers;
forming a first plurality of vias to the plurality of second ground layers in the first dielectric layer;
depositing a second dielectric layer on or above the first dielectric layer and the first plurality of vias; and
forming a first plate type ground layer having a slot, on, in or above the second dielectric layer, in electrical contact with the first plurality of vias.

15. The method of claim 14, further comprising forming a second plurality of vias in the second dielectric layer, and depositing a third dielectric layer on or above the second dielectric layer and the second plurality of vias.

16. The method of claim 15, wherein the first plate type ground layer is formed in or on the third dielectric layer, in electrical contact with the second plurality of vias.

17. The method according to claim 14, further comprising forming a plurality of slots in the first ground layer.

18. The method according to claim 14, further comprising forming a third plate type ground layer on the insulating layer and connected to the second ground layer.
